(19) United States
(12) Patent Application Publication
(10) Pub. No.: US 2025/0063956 A1
(43) Pub. Date: Feb. 20, 2025

(54) SEMICONDUCTOR STRUCTURE, SEMICONDUCTOR DEVICE AND MANUFACTURING METHOD THEREOF

(71) Applicant: Taiwan Semiconductor Manufacturing Company, Ltd., Hsinchu (TW)

(72) Inventors: Tzu-Yu CHEN, Hsinchu (TW); Sheng-Hung SHIH, Hsinchu (TW); Kuo-Chi TU, Hsinchu (TW); Wen-Ting CHU, Hsinchu (TW); Kuo-Ching HUANG, Hsinchu (TW); Harry-Haklay CHUANG, Hsinchu (TW)

(73) Assignee: Taiwan Semiconductor Manufacturing Company, Ltd., Hsinchu (TW)

(21) Appl. No.: 18/235,391

(22) Filed: Aug. 18, 2023

(51) Int. Cl. H10N 70/20; H10N 70/00

(52) U.S. Cl. CPC H10N 70/25; H10N 70/011; H10N 70/8265

(57) ABSTRACT

A semiconductor structure includes a ferroelectric layer and a semiconductor layer. Thee ferroelectric layer has a first surface and a second surface opposite to the first surface. The semiconductor layer is formed on one of the first surface and the second surface.

### BACKGROUND

Ferroelectricity is a characteristic of certain materials that have a spontaneous electric polarization that can be reversed by the application of an external electric field. Recent interest is the ferroelectric tunnel junction (FTJ) in which a contact is made up by nanometer-thick ferroelectric film placed between metal electrodes. However, a poor interface material between the ferroelectric film and the metal electrodes of FTJ may degrade 2-state current of FTJ.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a cross-sectional view of a semiconductor structure according to an embodiment of the present disclosure.

FIG. 2 illustrates a schematic diagram of a cross-sectional view of a semiconductor structure according to an embodiment of the present disclosure.

FIG. 3 illustrates a schematic diagram of a cross-sectional view of a semiconductor structure according to an embodiment of the present disclosure.

FIG. 4 illustrates a schematic diagram of a cross-sectional view of a semiconductor device according to an embodiment of the present disclosure.

FIG. 5 illustrates a schematic diagram of a cross-sectional view of a semiconductor device according to an embodiment of the present disclosure.

FIG. 6 illustrates a schematic diagram of a cross-sectional view of a semiconductor device according to an embodiment of the present disclosure.

FIG. 7 illustrates a schematic diagram of a cross-sectional view of a semiconductor device according to an embodiment of the present disclosure.

FIG. 8 illustrates a schematic diagram of a cross-sectional view of a semiconductor device according to an embodiment of the present disclosure.

FIGS. 9A to 9K illustrate schematic diagrams of manufacturing processes of the semiconductor device in FIG. 4.

FIGS. 10A to 10E illustrate schematic diagrams of manufacturing processes of the semiconductor device in FIG. 5.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Referring to FIG. 1, FIG. 1 illustrates a schematic diagram of a cross-sectional view of a semiconductor structure 10 according to an embodiment of the present disclosure. The semiconductor structure 10 is, for example, a FTJ (Ferroelectric Tunnel Junction) MFS (metal/ferroelectric/semiconductor).

As illustrated in FIG. 1, the semiconductor structure 10 includes a ferroelectric layer 11, a semiconductor layer 12, a bottom electrode 13 and a top electrode 14. The ferroelectric layer 11 has a first surface 11s1 and a second surface 11s2 opposite to the first surface 11s1. The semiconductor layer 12 is formed over the first surface 11s1 of the ferroelectric layer 11. The ferroelectric layer 11 is formed between the bottom electrode 13 and the semiconductor layer 12. In the present embodiment, the semiconductor layer 12 could generate a band bending. As a result, the interaction layer (IL) (for example, Al₂O₃ layer) is not required between the semiconductor layer 12 and the ferroelectric layer 11, and thus it could improve the tunneling current efficiency (enlarge 2-state current of FTJ), ease to scaling down for interfacial layer removing and/or easily combine with logic process as embedded memory.

In solid-state physics, band bending refers to the process in which the electronic band structure in a material curves up or down near a junction or interface. It does not involve any physical (spatial) bending. When the electrochemical potential of the free charge carriers around an interface of a semiconductor is dissimilar, charge carriers are transferred between the two materials until an equilibrium state is reached whereby the potential difference vanishes.

As illustrated in FIG. 1, the semiconductor layer 12 may be in directly contact with the ferroelectric layer 11. In other words, there is no any physical material (for example, the interaction layer) between the ferroelectric layer 11 and the semiconductor layer 12. As a result, it could reduce the impedance between the ferroelectric layer 11 and the semiconductor layer 12.

As illustrated in FIG. 1, the ferroelectric layer 11 has a thickness T₁₁ ranging between 10 angstrom (Å) and 200 Å. The ferroelectric layer 11 may be formed of a material including, for example, SBT (SrBi₂Ta₂O₉), PZT (PbZrTi), HZO (HfZrO₂), Zr (Zirconium), Si (Silicon), Y (Yttrium), Al (Aluminum), Gd (Gadolinium), La (Lanthanum), Sr (Strontium), Si doped HfO₂ or a combination thereof.

As illustrated in FIG. 1, the semiconductor layer 12 has a thickness T₁₂ ranging between 2 angstrom (Å) and 300 Å. The semiconductor layer 12 may be formed of a material including, for example, Ge (Germanium), GeTe, GeSb, SiGe, a-Si (amorphous silicon), IGZO (Indium Gallium Zinc Oxide) or a combination thereof.

As illustrated in FIG. 1, the bottom electrode 13 is formed under the ferroelectric layer 11. The bottom electrode 13 may be formed of a material including, for example, TiN, TaN, Ru, (Molybdenum), W (Tungsten) or a combination thereof. The top electrode 14 is formed above the semiconductor layer 12. The top electrode 14 may be formed of a material including TIN, TaN, Ru (Ruthenium), Mo, W or a combination thereof. In terms of structure, the electrode could be a single-layered electrode or a multi-layered electrode.

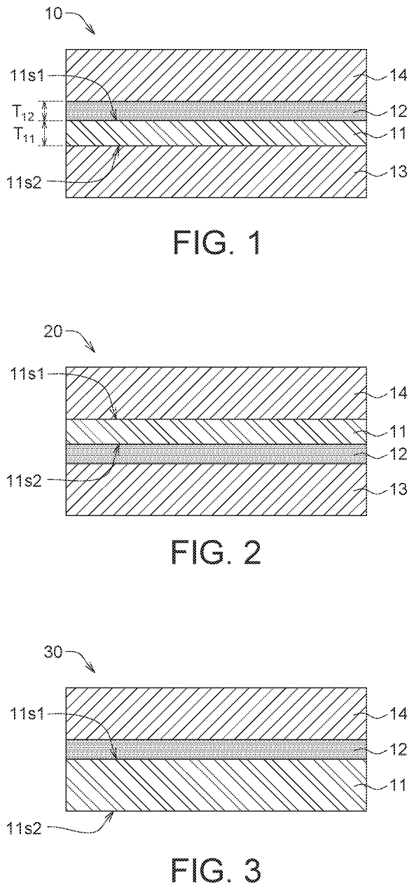

Referring to FIG. 2, FIG. 2 illustrates a schematic diagram of a cross-sectional view of a semiconductor structure 20 according to an embodiment of the present disclosure. The semiconductor structure 20 is, for example, a FTJ MFS.

As illustrated in FIG. 2, the semiconductor structure 20 includes the ferroelectric layer 11, the semiconductor layer 12, the bottom electrode 13 and the top electrode 14. The semiconductor layer 12 is formed between the bottom electrode 13 and the ferroelectric layer 11. The semiconductor layer 12 is formed on the second surface 11s2 of the ferroelectric layer 11. In the present embodiment, the semiconductor layer 12 could generate a band bending. As a result, the interaction layer is not required between the semiconductor layer 12 and the ferroelectric layer 11, and thus it could improve the tunneling current efficiency (enlarge 2-state current of FTJ), ease to scaling down for interfacial layer removing and/or easily combine with logic process as embedded memory.

As illustrated in FIG. 2, the bottom electrode 13 is formed under the semiconductor layer 12. The top electrode 14 is formed above the ferroelectric layer 11.

Referring to FIG. 3, FIG. 3 illustrates a schematic diagram of a cross-sectional view of a semiconductor structure 30 according to an embodiment of the present disclosure. The semiconductor structure 30 is, for example, a FTJ MFS.

As illustrated in FIG. 3, the semiconductor structure 30 includes the ferroelectric layer 11, the semiconductor layer 12 and the top electrode 14. The semiconductor layer 12 is formed between the top electrode 14 and the ferroelectric layer 11. The semiconductor layer 12 is formed over the first surface 11s1 of the ferroelectric layer 11. The semiconductor layer 12 could generate a band bending. As a result, the interaction layer is not required between the semiconductor layer 12 and the ferroelectric layer 11, and thus it could improve the tunneling current efficiency (enlarge 2-state current of FTJ), ease to scaling down for interfacial layer removing and/or easily combine with logic process as embedded memory.

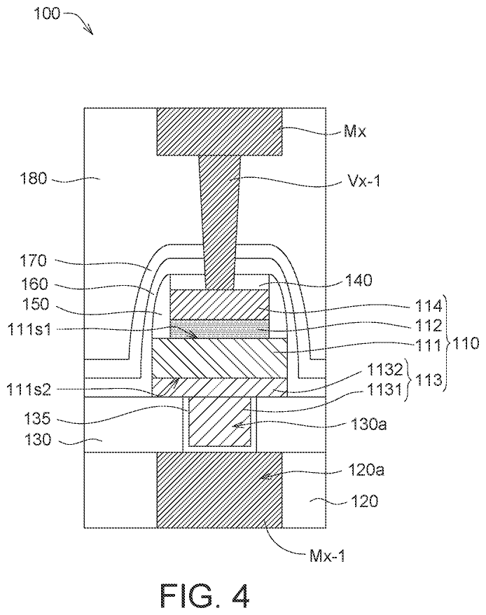

Referring to FIG. 4, FIG. 4 illustrates a schematic diagram of a cross-sectional view of a semiconductor device 100 according to an embodiment of the present disclosure. The semiconductor device 100 is, for example, a device including FTJ MFS.

As illustrated in FIG. 4, the semiconductor device 100 includes at least one semiconductor structure 110, an oxide layer 120, a metal layer Mₓ₋₁ (for example, M0, M1, M2, etc., as defined in the semiconductor field), an insulation layer 130, an interposer layer 135, an insulation layer 140, a spacer 150, an insulation layer 160, an oxide layer 170, an oxide layer 180, at least one metal via Vₓ₋₁ and at least one metal layer Mₓ. The value “x” may be positive integer equal to or greater than 1.

As illustrated in FIG. 4, in the present embodiment, the semiconductor structure 110 may be formed in/on a BEOL (Back End of Line) structure. The semiconductor structure 110 includes a ferroelectric layer 111, a semiconductor layer 112, a bottom electrode 113 and a top electrode 114. The ferroelectric layer 111 has a first surface 111s1 and a second surface 111s2 opposite to the first surface 11s1. The semiconductor layer 112 is formed on the first surface 111s1 of the ferroelectric layer 111. The ferroelectric layer 111 is formed between the bottom electrode 113 and the semiconductor layer 112. The semiconductor layer 112 could generate a band bending. As a result, the interaction layer is not required between the semiconductor layer 112 and the ferroelectric layer 111, and thus it could improve the tunneling current efficiency.

As illustrated in FIG. 4, the ferroelectric layer 111, the semiconductor layer 112, the bottom electrode 113 and the top electrode 114 include the features (structure, material and/or connection relationship) the same as or similar to that of the ferroelectric layer 11, semiconductor layer 12, the bottom electrode 13 and the top electrode 14 respectively.

As illustrated in FIG. 4, the bottom electrode 113 includes a conductive via 1131 and a conductive layer 1132. The conductive via 1131 is formed within a through hole 130a of the insulation layer, and the conductive layer 1132 is formed over the insulation layer 130 and connected with the conductive via 1131.

As illustrated in FIG. 4, the oxide layer 120 has at least one through hole 120a, and the metal layer Mₓ₋₁ is formed within the through hole 120a to be electrically connected to a FEOL (Front End of Line) structure (not illustrated) formed under the oxide layer 120. The insulation layer 130 is formed over the oxide layer 120 and has at least one through hole 130a. The insulation layer 130 is formed of, for example, SiC (silicon carbide). The interposer layer 135 is formed on a sidewall of the through hole 130. The interposer layer 135 is formed of, for example, TaN. The semiconductor structure 110 is formed over the insulation layer 130 and electrically connected to the metal layer Mₓ₋₁. Furthermore, the bottom electrode 113 of the semiconductor structure 110 is electrically connected to the metal layer Mₓ₋₁ through the through via 130.

As illustrated in FIG. 4, the insulation layer 140 is formed on the semiconductor structure 110, for example, the top electrode 114 of the semiconductor structure 110. The insulation layer 140 is formed of, for example, SiON. The spacer 150 is formed on the ferroelectric layer 111 and over sidewalls of, the semiconductor layer 112, the top electrode 114 and the insulation layer 140. The insulation layer 160 is formed over the semiconductor structure 110. The insulation layer 160 is formed of, for example, SiC. The oxide layer 170 is formed over the insulation layer 160. The oxide layer 180 is formed over the oxide layer 170. The metal via Vₓ₋₁ passes through the oxide layer 180, the oxide layer 170, the insulation layer 160 and the insulation layer 140 to be electrically connected to the semiconductor structure 110, for example, the top electrode 114. The metal layer Mₓ is formed on and electrically connected to the metal via Vₓ₋₁.

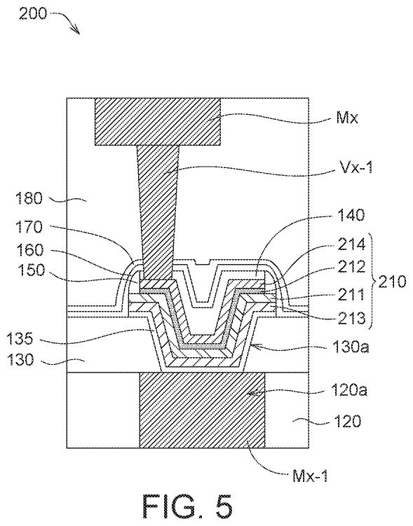

Referring to FIG. 5, FIG. 5 illustrates a schematic diagram of a cross-sectional view of a semiconductor device 200 according to an embodiment of the present disclosure. The semiconductor device 200 is, for example, a device including FTJ MFS.

As illustrated in FIG. 5, the semiconductor device 200 includes at least one semiconductor structure 210, the oxide layer 120, the metal layer Mₓ₋₁, the insulation layer 130, the interposer layer 135, the insulation layer 140, the spacer 150, the insulation layer 160, the oxide layer 170, the oxide layer 180, at least one metal via Vₓ₋₁ and at least one metal layer Mₓ.

As illustrated in FIG. 5, in the present embodiment, the semiconductor structure 110 may be formed in/on a BEOL structure. The semiconductor structure 210 includes a ferroelectric layer 211, a semiconductor layer 212, a bottom electrode 213 and a top electrode 214. The ferroelectric layer 211 is formed between the bottom electrode 213 and the semiconductor layer 212. The semiconductor layer 212 could generate a band bending. As a result, the interaction layer is not required between the semiconductor layer and the ferroelectric layer, and thus it could improve the tunneling current efficiency (enlarge 2-state current of FTJ), ease to scaling down for interfacial layer removing and/or easily combine with logic process as embedded memory.

As illustrated in FIG. 5, the ferroelectric layer 211, the semiconductor layer 212, the bottom electrode 213 and the top electrode 214 include the features (structure, material and/or connection relationship) the same as or similar to that of the ferroelectric layer 111, semiconductor layer 112, the bottom electrode 113 and the top electrode 114 respectively.

As illustrated in FIG. 5, the oxide layer 120 has at least one through hole 120a, and the metal layer Mₓ₋₁ is formed within the through hole 120a to be electrically connected to a FEOL structure (not illustrated) formed under the oxide layer 120. The insulation layer 130 is formed over the oxide layer 120 and has at least one through hole 130a. The insulation layer 130 is formed of, for example, SiC. The interposer layer 135 is formed on a sidewall of the through hole 130. The semiconductor structure 210 is formed over the insulation layer 130 and electrically connected to the metal layer Mₓ₋₁. Furthermore, the bottom electrode 213 of the semiconductor structure 210 is electrically connected to the metal layer Mₓ₋₁ through the through via 130a.

As illustrated in FIG. 5, the insulation layer 140 is formed on the semiconductor structure 210, for example, the top electrode 214 of the semiconductor structure 110. The spacer 150 is formed on the ferroelectric layer 211 and over sidewalls of the insulation layer 140, the semiconductor layer 212 and the top electrode 214. The insulation layer 160 is formed over the semiconductor structure 210. The oxide layer 170 formed over the insulation layer 160. The oxide layer 180 is formed over the oxide layer 170. The metal via Vₓ₋₁ passes through the oxide layer 180, the oxide layer 170, the insulation layer 160 and the insulation layer 140 to be electrically connected to the semiconductor structure 210, for example, the top electrode 214. The metal layer Mₓ is formed on the metal via Vₓ₋₁ to be electrically connected to the metal via Vₓ₋₁.

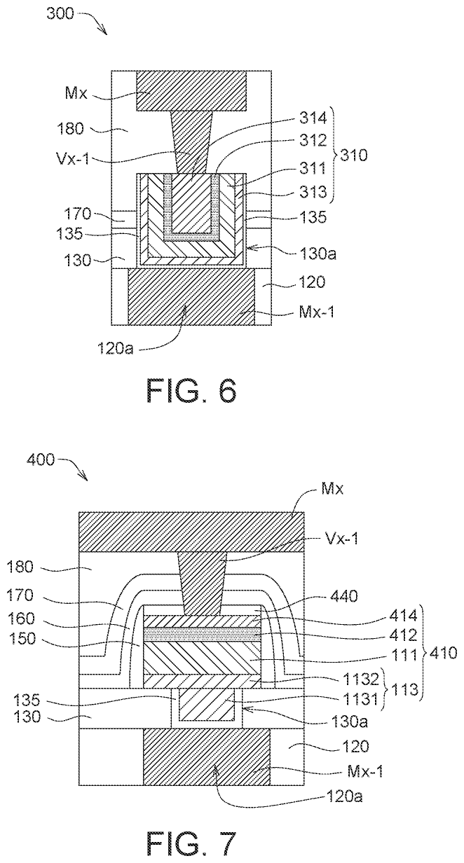

Referring to FIG. 6, FIG. 6 illustrates a schematic diagram of a cross-sectional view of a semiconductor device 300 according to an embodiment of the present disclosure. The semiconductor device 300 is, for example, a device including FTJ MFS.

As illustrated in FIG. 6, the semiconductor device 300 includes at least one semiconductor structure 310, the oxide layer 120, the metal layer Mₓ₋₁, the insulation layer 130, the interposer layer 135, the oxide layer 170, the oxide layer 180, at least one metal via Vₓ₋₁ and at least one metal layer Mₓ.

As illustrated in FIG. 6, in the present embodiment, the semiconductor structure 310 may be formed in/on a BEOL structure. The semiconductor structure 310 includes a ferroelectric layer 311, a semiconductor layer 312, a bottom electrode 313 and a top electrode 314. The ferroelectric layer 311 is formed between the bottom electrode 313 and the semiconductor layer 312. The semiconductor layer 312 could generate a band bending. As a result, the interaction layer is not required between the semiconductor layer and the ferroelectric layer, and thus it could improve the tunneling current efficiency (enlarge 2-state current of FTJ), ease to scaling down for interfacial layer removing and/or easily combine with logic process as embedded memory.

As illustrated in FIG. 6, the ferroelectric layer 311, the semiconductor layer 312, the bottom electrode 313 and the top electrode 314 include the features (structure, material and/or connection relationship) the same as or similar to that of the ferroelectric layer 111, semiconductor layer 112, the bottom electrode 113 and the top electrode 114 respectively.

As illustrated in FIG. 6, the oxide layer 120 has at least one through hole 120a, and the metal layer Mₓ₋₁ is formed within the through hole 120a to be electrically connected to a FEOL structure (not illustrated) formed under the oxide layer 120. The insulation layer 130 is formed over the oxide layer 120. The semiconductor device 300 has at least one through hole 130a, wherein the through hole 130a passes through the insulation layer 130, the oxide layer 170 and a portion of the oxide layer 180. The interposer layer 135 is formed on a sidewall of the through hole 130a. The semiconductor structure 310 is formed over the interposer layer 135 and electrically connected to the metal layer Mₓ₋₁. Furthermore, the bottom electrode 313 of the semiconductor structure 310 is electrically connected to the metal layer Mₓ₋₁ through the through via 130a.

As illustrated in FIG. 6, the oxide layer 170 is formed over the insulation layer 130. The oxide layer 180 is formed over the oxide layer 170 and the semiconductor structure 310. The metal via Vₓ₋₁ passes through the oxide layer 180 to be electrically connected to the semiconductor structure 310, for example, the top electrode 314. The metal layer Mₓ is formed on the metal via Vₓ₋₁ to be electrically connected to the metal via Vₓ₋₁.

Referring to FIG. 7, FIG. 7 illustrates a schematic diagram of a cross-sectional view of a semiconductor device 400 according to an embodiment of the present disclosure. The semiconductor device 400 is, for example, a device including FTJ MFS.

As illustrated in FIG. 7, the semiconductor device 400 includes at least one semiconductor structure 410, the oxide layer 120, the metal layer Mₓ₋₁, the insulation layer 130, the interposer layer 135, an insulation layer 440, the spacer 150, the insulation layer 160, the oxide layer 170, the oxide layer 180, at least one metal via Vₓ₋₁ and at least one metal layer Mₓ.

As illustrated in FIG. 7, in the present embodiment, the semiconductor structure 410 may be formed in/on a BEOL structure. The semiconductor structure 410 includes the ferroelectric layer 111, a semiconductor layer 412, the bottom electrode 113 and a top electrode 414. The ferroelectric layer 111 is formed between the bottom electrode 113 and the semiconductor layer 412. The semiconductor layer 412 could generate a band bending. As a result, the interaction layer is not required between the semiconductor layer and the ferroelectric layer, and thus it could improve the tunneling current efficiency (enlarge 2-state current of FTJ), ease to scaling down for interfacial layer removing and/or easily combine with logic process as embedded memory.

As illustrated in FIG. 7, the ferroelectric layer 111, the semiconductor layer 412, the bottom electrode 113 and the top electrode 414 include the features (structure, material and/or connection relationship) the same as or similar to that of the ferroelectric layer 111, semiconductor layer 112, the bottom electrode 113 and the top electrode 114 in FIG. 4 respectively.

As illustrated in FIG. 7, the bottom electrode 113 includes a conductive via 1131 and a conductive layer 1132. The conductive via 1131 is formed within the through via 130a and the conductive layer 1132 is formed over and electrically connected to the conductive via 1131.

As illustrated in FIG. 7, the oxide layer 120 has at least one through hole 120a, and the metal layer Mas is formed within the through hole 120a to be electrically connected to a FEOL structure (not illustrated) formed under the oxide layer 120. The insulation layer 130 is formed over the oxide layer 120 and has at least one through hole 130a. The interposer layer 135 is formed on a sidewall of the through hole 130. The semiconductor structure 410 is formed over the insulation layer 130 and electrically connected to the metal layer Mₓ₋₁. Furthermore, the bottom electrode 113 of the semiconductor structure 410 is electrically connected to the metal layer Mₓ₋₁ through the through via 130a.

As illustrated in FIG. 7, the insulation layer 440 is formed on the semiconductor structure 410, for example, the top electrode 414 of the semiconductor structure 410. The spacer 150 is formed on the insulation layer 130 and over sidewalls of the ferroelectric layer 111, the semiconductor layer 412, the bottom electrode 113, the top electrode 414 and the insulation layer 440. The insulation layer 160 is formed over the semiconductor structure 410. The oxide layer 170 formed over the insulation layer 160. The oxide layer 180 is formed over the oxide layer 170. The metal via Vₓ₋₁ passes through the oxide layer 180, the oxide layer 170, the insulation layer 160 and the insulation layer 440 to be electrically connected to the semiconductor structure 410, for example, the top electrode 414. The metal layer Mₓ is formed on the metal via Vₓ₋₁ to be electrically connected to the metal via Vₓ₋₁.

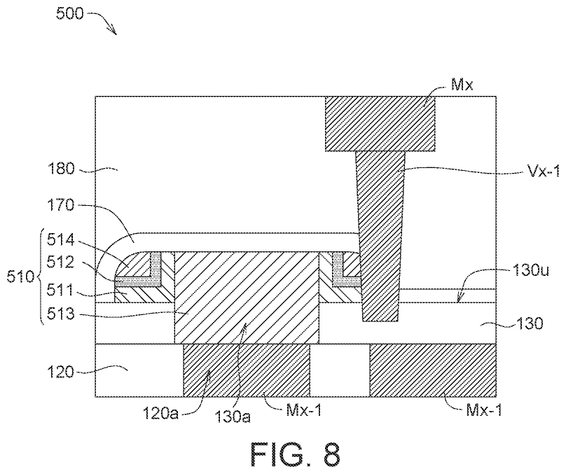

Referring to FIG. 8, FIG. 8 illustrates a schematic diagram of a cross-sectional view of a semiconductor device 500 according to an embodiment of the present disclosure. The semiconductor device 500 is, for example, a device including FTJ MFS.

As illustrated in FIG. 8, the semiconductor device 500 includes at least one semiconductor structure 510, the oxide layer 120, the metal layer Mₓ₋₁, the insulation layer 130, the oxide layer 170, the oxide layer 180, at least one metal via Vₓ₋₁ and at least one metal layer Mₓ.

As illustrated in FIG. 8, in the present embodiment, the semiconductor structure 510 may be formed in/on a BEOL structure. The semiconductor structure S10 includes a ferroelectric layer 511, a semiconductor layer 512, a bottom electrode 513 and a top electrode 514. The ferroelectric layer 511 is formed between the bottom electrode 513 and the semiconductor layer 512. The semiconductor layer 512 could generate a band bending. As a result, the interaction layer is not required between the semiconductor layer and the ferroelectric layer, and thus it could improve the tunneling current efficiency (enlarge 2-state current of FTJ), ease to scaling down for interfacial layer removing and/or easily combine with logic process as embedded memory.

As illustrated in FIG. 8, the ferroelectric layer 511, the semiconductor layer 512, the bottom electrode 513 and the top electrode 514 include the features (structure, material and/or connection relationship) the same as or similar to that of the ferroelectric layer 11, semiconductor layer 12, the bottom electrode 13 and the top electrode 14 respectively.

As illustrated in FIG. 8, the oxide layer 120 has at least one through hole 120a, and the metal layer Mₓ₋₁ is formed within the through hole 120a to be electrically connected to a FEOL structure (not illustrated) formed under the oxide layer 120. The insulation layer 130 is formed over the oxide layer 120 and has at least one through hole 130a. The semiconductor structure 510 is formed in/on the insulation layer 130 and electrically connected to the metal layer Mₓ₋₁.

As illustrated in FIG. 8, the bottom electrode 513 is formed in the through hole 130a of the insulation layer 130 and protrudes with respect to an upper surface 130u of the insulation layer 130. The ferroelectric layer 511 is formed on the upper surface 130u of the insulation layer 130 and over sidewall of the bottom electrode 513. The semiconductor layer 512 is formed on an upper surface of the ferroelectric layer 511 and over sidewall of the ferroelectric layer 511. The top electrode 514 is formed on an upper surface of the semiconductor layer S12 and over sidewall of the semiconductor layer 512.

As illustrated in FIG. 8, the oxide layer 170 formed over the semiconductor structure 510. The oxide layer 180 is formed over the oxide layer 170. The metal via Vₓ₋₁ passes through the oxide layer 180, the oxide layer 170, the top electrode 514, the semiconductor layer 512 and the ferroelectric layer 511 and to be electrically connected to the top electrode 514 of the semiconductor structure 510. The metal layer Mₓ is formed on the metal via Vₓ₋₁ to be electrically connected to the metal via Vₓ₋₁.

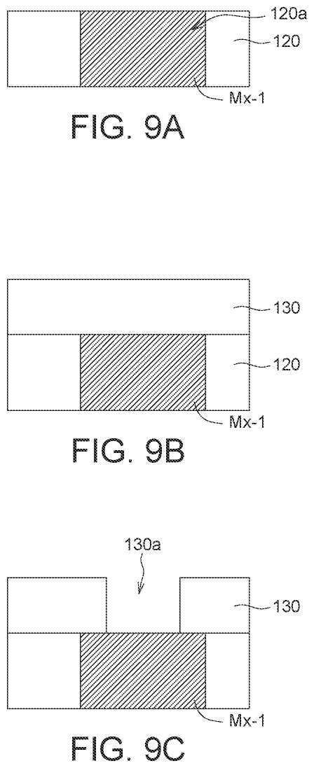

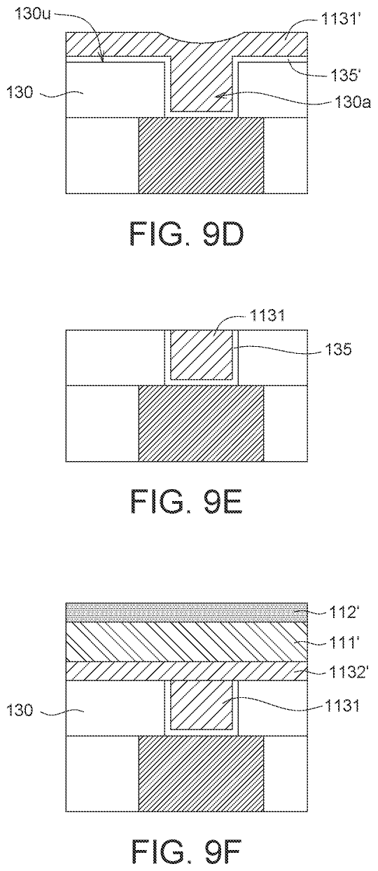

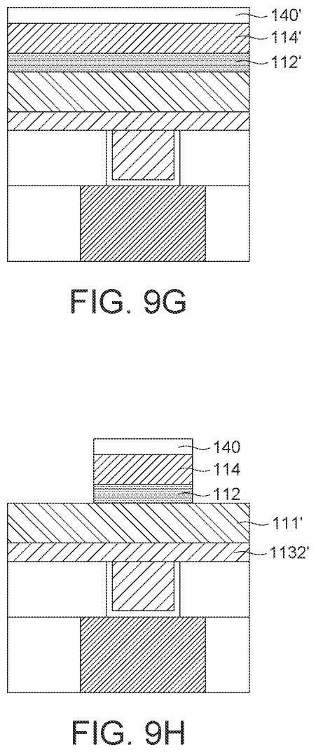

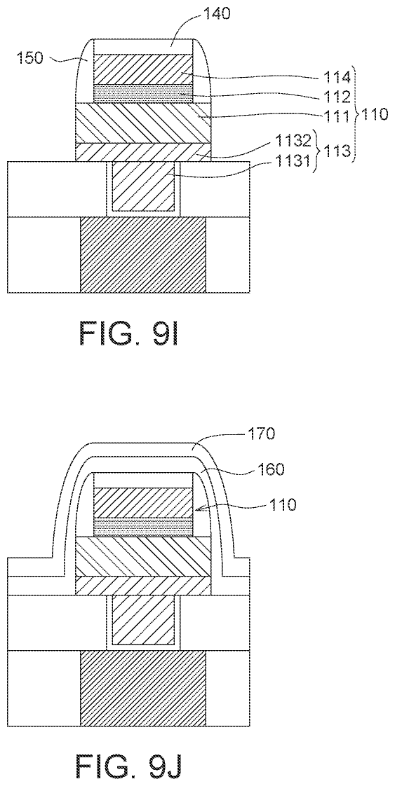

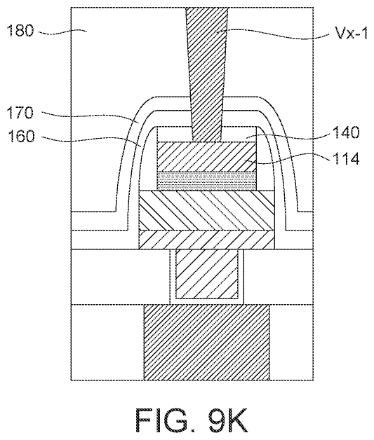

Referring to FIGS. 9A to 9K, FIGS. 9A to 9K illustrate schematic diagrams of manufacturing processes of the semiconductor device 100 in FIG. 4.

As illustrated in FIG. 9A, the oxide layer 120 having at least one through hole 120a is formed, and then the metal layer Mₓ₋₁ is formed within the through hole 120a. The oxide layer 120 and the metal layer Mₓ₋₁ may be planarized by using a CMP.

As illustrated in FIG. 9B, the insulation layer 130 is formed over the oxide layer 120 and the metal layer Mₓ₋₁ by using deposition process.

As illustrated in FIG. 9C, at least one through hole 130a passing through the insulation layer 130 is formed by using photolithography (exposure/development/etching), wherein the through hole 130a exposes the metal layer Mₓ₋₁.

As illustrated in FIG. 9D, an interposer layer material 135′ on the sidewalls of the through hole 130a and the upper surface 130u of the insulation layer 130 is formed by using, for example, deposition process, and then a conductive via material 1131′ over the interposer layer material 135′ and the insulation layer 130 is formed by using, for example, deposition process.

As illustrated in FIG. 9E, the conductive via material 1131′ is planarized to form the interposer layer 135 and the conductive via 1131 by using, for example, a CMP.

As illustrated in FIG. 9F, a conductive layer material 1132′, a ferroelectric layer material 11l′ and a semiconductor layer material 112′ are formed over the conductive via 1131 and the insulation layer 130 in order by using, for example, deposition process.

As illustrated in FIG. 9G, a top electrode material 114′ and an insulation layer material 140′ are formed over the semiconductor layer material 112′ in order by using, for example, deposition process.

As illustrated in FIG. 9H, a portion of the semiconductor layer material 112′, a portion of the top electrode material 114′ and a portion of the insulation layer material 140′ in FIG. 9G are removed to form the semiconductor layer 112, the top electrode 114 and the insulation layer 140 respectively by using, for example, photolithography.

As illustrated in FIG. 9I, a portion of the conductive layer material 1132′ and a portion of the ferroelectric layer material 111′ in FIG. 9H are removed to form the conductive layer 1132 and the ferroelectric layer 111 respectively by using, for example, photolithography. Then, the spacer 150 is formed on the ferroelectric layer 111 and over sidewall of the semiconductor layer 112, the top electrode 114 and the insulation layer 140 by using, for example, deposition and photolithography. The semiconductor structure 110 including the ferroelectric layer 111, the semiconductor layer 112, the bottom electrode 113 and the top electrode 114 is formed.

In another embodiment, the spacer 150 in FIG. 9I may be formed first, and then a portion of the conductive layer material 1132′ and a portion of the ferroelectric layer material 111′ are removed to form the conductive layer 1132 and the ferroelectric layer 111 respectively through the spacer 150 (as a mask, for example).

As illustrated in FIG. 9J, the insulation layer 160 over the semiconductor structure 110 is formed by using, for example, deposition, then the oxide layer 170 over the insulation layer 160 is formed by using, for example, deposition.

As illustrated in FIG. 9K, a portion of the insulation layer 180 in FIG. 4 over the oxide layer 170 is formed by using, for example, deposition. Then, at least one metal via Vₓ₋₁ passing through the insulation layer 180, the oxide layer 170, insulation layer 160 and the insulation layer 140 to be electrically connected the top electrode 114 is formed by using, for example, photolithography and deposition.

Then, another portion of the insulation layer 180 in FIG. 4 over the metal via Vₓ₋₁ is formed by using, for example, deposition. Then, at least one metal layer Mₓ on the metal via Vₓ₋₁ is formed by using, for example, photolithography and deposition. So far, the semiconductor device 100 in FIG. 4 is formed.

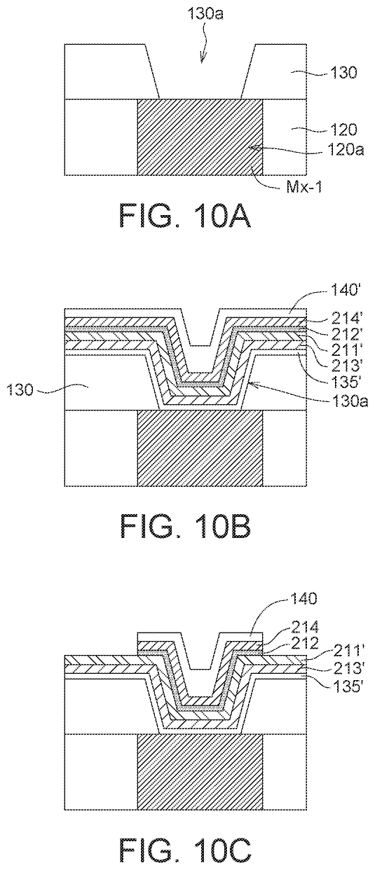

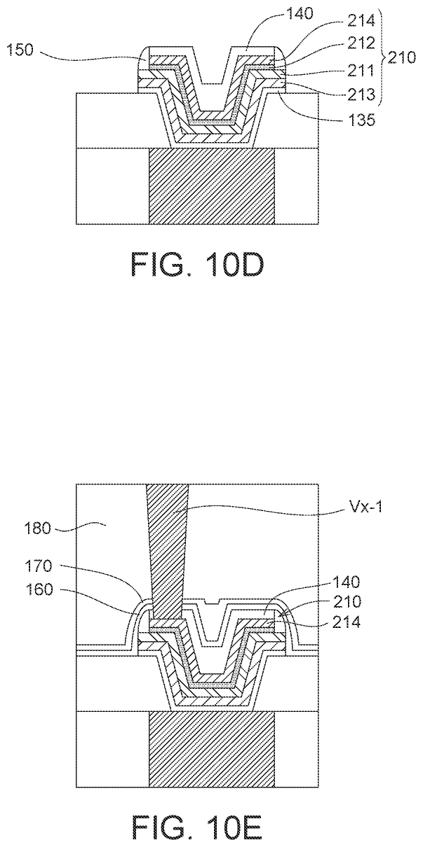

Referring to FIGS. 10A to 10E, FIGS. 10A to 10E illustrate schematic diagrams of manufacturing processes of the semiconductor device 200 in FIG. 5.

As illustrated in FIG. 10A, the oxide layer 120 having at least one through hole 120a is formed, and then the metal layer Mₓ₋₁ is formed within the through hole 120a. The oxide layer 120 and the metal layer Mₓ₋₁ are planarized by using a CMP. Then, the insulation layer 130 having at least one through hole 130a is formed by using, for example, deposition and photolithography.

As illustrated in FIG. 10B, the interposer layer material 135′, a bottom electrode material 213′, a ferroelectric layer material 211′, a semiconductor layer material 212′, a top electrode material 214′ and an insulation layer material 140′ are formed on the through hole 130a and the upper surface of the insulation layer 130 in order by using, for example, deposition process.

As illustrated in FIG. 10C, a portion of the semiconductor layer material 212′, a portion of the top electrode material 214′ and a portion of the insulation layer material 140′ in FIG. 10B are removed to form the semiconductor layer 212, the top electrode 214 and the insulation layer 140 by using, for example, photolithography.

As illustrated in FIG. 10D, a portion of the ferroelectric layer material 211′, a portion of the bottom electrode material 213′ and a portion of the interposer layer material 13S′ in FIG. 10C are removed to form the ferroelectric layer 211, the bottom electrode 213 and the interposer layer 135 respectively by using, for example, photolithography. Then, the spacer 150 is formed on the ferroelectric layer 211 and over sidewalls of the insulation layer 140, the semiconductor layer 212 and the top electrode 214 by using, for example, deposition. The semiconductor structure 210 including the ferroelectric layer 211, the semiconductor layer 212, the bottom electrode 213 and the top electrode 214 is formed.

In another embodiment, the spacer 150 in FIG. 10D may be formed first, and then a portion of the ferroelectric layer material 211′, a portion of the bottom electrode material 213′ and a portion of the interposer layer material 135′ are removed to form the ferroelectric layer 211, the bottom electrode 213 and the interposer layer 135 respectively through the spacer 150 (as a mask, for example).

As illustrated in FIG. 10E, the insulation layer 160 over the semiconductor structure 210 is formed by using, for example, deposition. Then, the oxide layer 170 over the insulation layer 160 is formed by using, for example, deposition. Then, a portion of the insulation layer 180 in FIG. 5 over the oxide layer 170 is formed by using, for example, deposition. Then, at least one metal via Vₓ₋₁ passing through the insulation layer 180, the oxide layer 170, insulation layer 160 and the insulation layer 140 to be electrically connected the top electrode 214 is formed by using, for example, photolithography and deposition.

Then, another portion of the insulation layer 180 over the metal via Vₓ₋₁ is formed by using, for example, deposition. Then, at least one metal layer Mₓ on the metal via Vₓ₋₁ is formed by using, for example, photolithography and deposition. So far, the semiconductor device 200 in FIG. 5 is formed.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor structure includes a ferroelectric layer and a semiconductor layer formed on the ferroelectric layer. Accordingly, any interaction layer is not required between the semiconductor layer and the ferroelectric layer, and thus it could improve the tunneling current efficiency.

Example embodiment 1: a semiconductor structure includes a ferroelectric layer and a semiconductor layer. Thee ferroelectric layer has a first surface and a second surface opposite to the first surface. The semiconductor layer is formed on one of the first surface and the second surface.

Example embodiment 2 based on Example embodiment 1: the semiconductor structure as claimed in claim 1 further includes a bottom electrode, and the ferroelectric layer is formed between the bottom electrode and the semiconductor layer.

Example embodiment 3 based on Example embodiment 1: the semiconductor structure as claimed in claim 1 further includes a bottom electrode, and the semiconductor layer is formed between the bottom electrode and the ferroelectric layer.

Example embodiment 4 based on Example embodiment 1: the semiconductor layer is in directly contact with the ferroelectric layer.

Example embodiment 5 based on Example embodiment 1: there is no interaction layer between the semiconductor layer and the ferroelectric layer.

Example embodiment 6 based on Example embodiment 1: the semiconductor layer has a thickness ranging between 2 Å and 300 Å.

Example embodiment 7 based on Example embodiment 1: the ferroelectric layer has a thickness ranging between 10 Å and 200 Å.

Example embodiment 8 based on Example embodiment 1: the semiconductor layer is formed of Ge, GeTe, GeSb, SiGe, a-Si, or IGZO

Example embodiment 9: a semiconductor device includes a semiconductor structure, an oxide layer and a metal via. The semiconductor structure includes a ferroelectric layer, a semiconductor layer and a top electrode. Thee ferroelectric layer has a first surface and a second surface opposite to the first surface. The semiconductor layer is formed on one of the first surface and the second surface. The top electrode is formed over the semiconductor layer. The oxide layer covers the semiconductor structure and the top electrode. The metal via passes through the oxide layer to electrically connect the top electrode.

Example embodiment 10 based on Example embodiment 9: the semiconductor structure as claimed in claim 1 further includes a bottom electrode, and the ferroelectric layer is formed between the bottom electrode and the semiconductor layer.

Example embodiment 11 based on Example embodiment 9: the semiconductor structure as claimed in claim 1 further includes a bottom electrode, and the semiconductor layer is formed between the bottom electrode and the ferroelectric layer.

Example embodiment 12 based on Example embodiment 9: the semiconductor layer is in directly contact with the ferroelectric layer.

Example embodiment 13 based on Example embodiment 9: there is no interaction layer between the semiconductor layer and the ferroelectric layer.

Example embodiment 14 based on Example embodiment 9: the semiconductor layer has a thickness ranging between 2 Å and 300 Å.

Example embodiment 15 based on Example embodiment 9: the ferroelectric layer has a thickness ranging between 10 Å and 200 Å.

Example embodiment 16 based on Example embodiment 9: the semiconductor layer is formed of Ge, GeTe, GeSb, SiGe, a-Si, or IGZO.

Example embodiment 17: a manufacturing method of a semiconductor device includes the following steps: forming a semiconductor structure, wherein the semiconductor structure includes a ferroelectric layer, a semiconductor layer and a top electrode, the ferroelectric layer has a first surface and a second surface opposite to the first surface, the semiconductor layer is formed on one of the first surface and the second surface, and the top electrode is formed over the semiconductor layer; forming an oxide layer to cover the semiconductor structure and the top electrode; and forming a metal via passing through the oxide layer to electrically connect the top electrode.

Example embodiment 18 based on Example embodiment 17: in forming the semiconductor structure, the semiconductor structure further includes a bottom electrode, and the ferroelectric layer is formed between the bottom electrode and the semiconductor layer.

Example embodiment 19 based on Example embodiment 17: in forming the semiconductor structure, the semiconductor structure further includes a bottom electrode, and the semiconductor layer is formed between the bottom electrode and the ferroelectric layer.

Example embodiment 20 based on Example embodiment 17: in forming the semiconductor structure, the semiconductor layer is in directly contact with the ferroelectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a ferroelectric layer having a first surface and a second surface opposite to the first surface; and
a semiconductor layer formed on one of the first surface and the second surface.

2. The semiconductor structure as claimed in claim 1, further comprising:
a bottom electrode;
wherein the ferroelectric layer is formed between the bottom electrode and the semiconductor layer.

3. The semiconductor structure as claimed in claim 1, further comprising:
a bottom electrode;
wherein the semiconductor layer is formed between the bottom electrode and the ferroelectric layer.

4. The semiconductor structure as claimed in claim 1, wherein the semiconductor layer is in directly contact with the ferroelectric layer.

5. The semiconductor structure as claimed in claim 1, wherein there is no interaction layer between the semiconductor layer and the ferroelectric layer.

6. The semiconductor structure as claimed in claim 1, wherein the semiconductor layer has a thickness ranging between 2 angstrom (Å) and 300 Å.

7. The semiconductor structure as claimed in claim 1, wherein the ferroelectric layer has a thickness ranging between 10 Å and 200 Å.

8. The semiconductor structure as claimed in claim 1, wherein the semiconductor layer is formed of Ge, GeTe, GeSb, SiGe, a-Si, or IGZO.

9. A semiconductor device, comprising:
a semiconductor structure, comprising:
a ferroelectric layer having a first surface and a second surface opposite to the first surface;
a semiconductor layer formed on one of the first surface and the second surface; and
a top electrode formed over the semiconductor layer;
an oxide layer covering the semiconductor structure and the top electrode; and
a metal via passing through the oxide layer to electrically connect the top electrode.

10. The semiconductor device as claimed in claim 9, wherein the semiconductor structure further comprises:
a bottom electrode;
wherein the ferroelectric layer is formed between the bottom electrode and the semiconductor layer.

11. The semiconductor device as claimed in claim 9, wherein the semiconductor structure further comprises:
a bottom electrode;
wherein the semiconductor layer is formed between the bottom electrode and the ferroelectric layer.

12. The semiconductor device as claimed in claim 9, wherein the semiconductor layer is in directly contact with the ferroelectric layer.

13. The semiconductor device as claimed in claim 9, wherein there is no dielectric layer between the semiconductor layer and the ferroelectric layer.

14. The semiconductor device as claimed in claim 9, wherein the semiconductor layer has a thickness ranging between 2 Å and 300 Å.

15. The semiconductor device as claimed in claim 9, wherein the ferroelectric layer has a thickness ranging between 10 Å and 200 Å.

16. The semiconductor device as claimed in claim 9, wherein the semiconductor layer is formed of Ge, GeTe, GeSb, SiGe, a-Si, or IGZO.

17. A manufacturing method of a semiconductor device, comprising:
forming a semiconductor structure, wherein the semiconductor structure comprises a ferroelectric layer, a semiconductor layer and a top electrode, the ferroelectric layer has a first surface and a second surface opposite to the first surface, the semiconductor layer is formed on one of the first surface and the second surface, and the top electrode is formed over the semiconductor layer;
forming an oxide layer to cover the semiconductor structure and the top electrode; and
forming a metal via passing through the oxide layer to electrically connect the top electrode.

18. The manufacturing method as claimed in claim 17, wherein, in forming the semiconductor structure, the semiconductor structure further comprises a bottom electrode, and the ferroelectric layer is formed between the bottom electrode and the semiconductor layer.

19. The manufacturing method as claimed in claim 17, wherein, in forming the semiconductor structure, the semiconductor structure further comprises a bottom electrode, and the semiconductor layer is formed between the bottom electrode and the ferroelectric layer.

20. The manufacturing method as claimed in claim 17, wherein, in forming the semiconductor structure, the semiconductor layer is in directly contact with the ferroelectric layer.
